(19) United States
(12) Patent Application Publication
(10) Pub. No.: US 2011/0291209 A1
(43) Pub. Date: Dec. 1, 2011

(54) MAGNETIC MEMORY DEVICE

(75) Inventors: Takashi TAKENAGA, Tokyo (JP); Ryoji MATSUDA, Kanagawa (JP); Junichi TSUCHIMOTO, Kanagawa (JP)

(73) Assignee: RENESAS ELECTRONICS CORPORATION

(21) Appl. No.: 13/150,719

(22) Filed: Jun. 1, 2011

(30) Foreign Application Priority Data
Jun. 1, 2010 (JP) 2010-125799

(51) Int. Cl. H01L 29/82

(52) U.S. Cl. 257/421; 257/E29.323

(57) ABSTRACT

To provide a magnetic memory device having an increased write current and improved reliability in writing. The magnetic memory device of the invention has a substrate, a write line provided over the substrate, a bit line placed with a space from the write line in a thickness direction of the substrate and extending in a direction crossing with an extending direction of the write line, and a magnetic memory element positioned between the write line and the bit line. The magnetic memory element has a pinned layer whose magnetization direction has been fixed and a recording layer whose magnetization direction changes, depending on an external magnetic field. The recording layer contains an alloy film. The alloy film contains cobalt, iron, and boron and its boron content exceeds 21 at %.

### CROSS-REFERENCE TO RELATED APPLICATIONS

The disclosure of Japanese Patent Application No. 2010-125799 filed on Jun. 1, 2010 including the specification, drawings and abstract is incorporated herein by reference in its entirety.

### BACKGROUND OF THE INVENTION

The present invention relates to a magnetic memory device, particularly a magnetic memory device using a magnetoresistive effect element having tunneling magnetoresistive effect.

Magnetoresistive (MR) effect is a phenomenon in which when a magnetic field is applied to a magnetic material, electric resistance of it changes. This phenomenon is utilized for magnetic field sensors, magnetic heads, and the like. In particular, artificial lattice films of Fe/Cr, Co/Cu, and the like are introduced in Non-patent Documents 1 and 2 as giant magnetoresistive (GMR) effect materials showing tremendous magnetoresistive effect.

There is proposed a magnetoresistive effect element using a stack structure comprised of a ferromagnetic layer/nonmagnetic layer/ferromagnetic layer/anti-ferromagnetic layer and having a non-magnetic metal layer thick enough to eliminate an exchange coupling effect between the ferromagnetic layers. In this element, the ferromagnetic layer and the anti-ferromagnetic layer are exchanged-coupled with each other so that the magnetic moment of the ferromagnetic layer is fixed, while only the spin of the other ferromagnetic layer can be easily reversed by an external magnetic field. This element is known as so called “spin valve film”. Since in this element, exchange coupling between two ferromagnetic layers is weak, the spin can be reversed by a small magnetic field. The spin valve film can therefore provide a magnetoresistive element having higher sensitivity than the above exchange coupling film can. As the anti-ferromagnetic material, FeMn, IrMn, PtMn, or the like is used. This spin valve film is used by supplying a current in the in-plane direction of the film. Because of the characteristics described above, it is used for high-density magnetic read/write head.

Non-patent Document 3 shows that using a perpendicular magnetoresistive effect of supplying an electric current in a direction perpendicular to the plane of the film provides a further larger magnetoresistive effect.

Further, a tunneling magnetoresistive (TMR) effect due to the ferromagnetic tunnel junction is shown in Non-patent Document 4. This tunneling magnetoresistance utilizes the fact that in a three-layer film formed of a ferromagnetic layer, an insulating layer, and a ferromagnetic layer, the magnitude of the tunnel current in the direction perpendicular to the plane of the film changes by arranging the spins of the two ferromagnetic layers to be parallel or anti-parallel to each other by an external magnetic field.

In recent years, studies on the use of GMR or TMR elements for a nonvolatile magnetic memory semiconductor device (MRAM: magnetic random access memory) have been shown in, for example, Non-patent Documents 5 to 7.

In this case, pseudo spin valve elements or ferromagnetic tunneling effect elements having a nonmagnetic metal layer sandwiched between two ferromagnetic layers different in coercivity are studied. When these elements are used for an MRAM, “1” or “0” is recorded by arranging them in a matrix form, supplying a current to a wiring provided separately to apply a magnetic field, and controlling two magnetic layers forming each element to be parallel or anti-parallel to each other. Reading is performed using GMR or TMR effect.

An MRAM making use of a TMR effect consumes lower power than that making use of a GMR effect so that using the TMR element is mainly studied. In the MRAM using the TMR element, an output voltage is greater because an MR change ratio at room temperature is as large as 20% or greater and resistance at the tunnel junction is great. The MRAM using the TMR element does not need spin reversal at the time of reading, which enables reading at a small current. The MRAM using the TMR element is therefore expected as a low power consumption type nonvolatile semiconductor memory device capable of high-speed writing and reading.

In the write operation of the MRAM, control of the magnetic property of the ferromagnetic layer in the TMR element is desired. Described specifically, there are demands for a technology of controlling the relative magnetization directions of two ferromagnetic layers having a non-magnetic layer therebetween to be parallel or anti-parallel to each other and a technology of reliably and efficiently causing magnetic switching of one of the magnetic layers in a desired cell. For example, Patent Documents 1, 3, and 4 describe a technology of controlling the relative magnetization direction of two ferromagnetic layers having a non-magnetic layer therebetween to be uniformly parallel or anti-parallel to each other within the plane of the film by using two wirings intersecting each other.

In an MRAM, when cell size reduction is performed to achieve higher integration, a magnetic switching field increases due to a demagnetizing field, depending on the size of the magnetic layer in the film plane direction. As a result, a large magnetic field is required upon writing, which leads to an increase in power consumption. As shown in Patent Documents 2, 5, and 6, there is therefore proposed a technology of optimizing the shape of the ferromagnetic layer, thereby facilitating the magnetization switching.

When size reduction in the magnetic memory element is performed to satisfy higher integration in the MRAM, a further great magnetic field is required upon writing due to the influence of the demagnetizing field. In addition, a variation in the characteristic among elements attributable to their material or shape increases, whereby a further increase in the write current or incorrect magnetization switching becomes eminent. With regards to the material, size reduction makes it impossible to ignore the influence of the size of crystal grains on the size of the cell.

[Patent Document]

[Patent Document 1] Japanese Patent Laid-Open No. 273337/1999

[Patent Document 2] Japanese Patent Laid-Open No. 2002-280637

[Patent Document 3] Japanese Patent Laid-Open No. 2000-353791

[Patent Document 4] U.S. Pat. No. 6,005,800

[Patent Document 5] Japanese Patent Laid-Open No. 2004-296858

[Patent Document 6] U.S. Pat. No. 6,570,783

[Patent Document 7] Japanese Patent Laid-Open No. 2005-310971

[Non-Patent Document 1] D. H. Mosca et al., “Oscillatory interlayer coupling and giant magnetoresistance in Co/Cu multilayers”, Journal of Magnetism and Magnetic Materials 94 (1991) pp. L1-L5

[Non-Patent Document 2] S. S. P. Parkin et al., “Oscillatory Magnetic Exchange Coupling through Thin Copper Layers”, Physical Review Letters, vol. 66, No. 16, 22 Apr. 1991, pp. 2152-2155

[Non-Patent Document 3] W. P. Pratt et al., “Perpendicular Giant Magnetoresistances of Ag/Co Multilayers”, Physical Review Letters, vol. 66, No. 23, 10 Jun. 1991, pp. 3060-3063

[Non-Patent Document 4] T. Miyazaki et al., “Giant magnetic tunneling effect in Fe/Al₂O₃/Fe junction”, Journal of Magnetism and Magnetic Materials 139 (1995), pp. L231-L234

[Non-Patent Document 5] S. Tehrani et al., “High density submicron magnetoresistive random access memory (invited)”, Journal of Applied Physics, vol. 85, No. 8, 15 Apr. 1999, pp. 5822-5827

[Non-Patent Document 6] S. S. P. Parkin et al., “Exchange-biased magnetic tunnel junctions and application to nonvolatile magnetic random access memory (invited)”, Journal of Applied Physics, vol. 85, No. 8, 15 Apr. 1999, pp. 5828-5833

[Non-Patent Document 7] ISSCC 2001 Dig of Tech. Papers, p. 122

### SUMMARY OF THE INVENTION

In order to control the relative magnetization directions of two magnetic layers having therebetween a non-magnetic layer to the same direction or opposite directions; to reliably and efficiently achieve magnetization switching of one of the magnetic layers of a desired magnetic memory element; and to reduce the magnitude of a demagnetizing field which depends on the size of the magnetic layer in the film plane direction, it is presumed to be effective to optimize the material of a ferromagnetic material which undergoes magnetization switching by an external magnetic field and to optimize the shape of it.

As a result of extensive efforts for the above-described optimization of the material of a ferromagnetic layer, the present inventors have found that there appears an increase in magnetic switching field or distribution in magnetic switching field due to the heat treatment during manufacturing steps, depending on the material selected for a ferromagnetic layer. An increase in magnetic switching field leads to an increase in write current, while distribution in magnetic switching field leads to deterioration of reliability in writing.

With the above-described problems in view, the present invention has been made. An object of the invention is to provide a magnetic memory device having reduced write current and improved reliability in writing.

The magnetic memory device according to the invention is equipped with a substrate, a first wiring provided over the substrate, a second wiring placed with a space from the first wiring in the thickness direction of the substrate and extending in a direction intersecting with the extending direction of the first wiring, and a magnetic memory element positioned between the first wiring and the second wiring. The magnetic memory element includes a pinned layer whose magnetization direction has been fixed and a recording layer whose magnetization direction changes by an external magnetic field. The recording layer contains an alloy film and the alloy film contains cobalt, iron, and boron. The boron content is greater than 21 at %. The atomic percent (at %) means the number of atoms of a specific element assuming that the total number of atoms of the substance is 100.

The present invention makes it possible to provide a magnetic memory device having reduced write current and improved reliability in writing.

### BRIEF DESCRIPTION OF DRAWINGS

FIG. 1 is a circuit diagram of a memory cell of a magnetic memory device according to a first embodiment of the invention;

FIG. 2 is a schematic cross-sectional view showing the configuration of the magnetic memory device according to the first embodiment of the invention;

FIG. 3 is a perspective view schematically illustrating the configuration of the vicinity of a magnetic memory element MM;

FIG. 4 is a cross-sectional view schematically showing the configuration of the magnetic memory element of the magnetic memory device according to the first embodiment of the invention;

FIG. 5 is a schematic view showing the shape, in planar view, of the magnetic memory element according to the first embodiment of the invention;

FIG. 6 is an explanatory view of the position of the magnetic memory element MM according to the first embodiment of the invention and it is a see-through plan view of the magnetic memory element;

FIG. 7 is a schematic cross-sectional view showing a first step of a manufacturing method of the magnetic memory device according to the first embodiment of the invention;

FIG. 8 is a schematic cross-sectional view showing a second step of the manufacturing method of the magnetic memory device according to the first embodiment of the invention;

FIG. 9 is a schematic cross-sectional view showing a third step of the manufacturing method of the magnetic memory device according to the first embodiment of the invention;

FIGS. 10A and 10B are schematic cross-sectional views showing a fourth step of the manufacturing method of the magnetic memory device according to the first embodiment of the invention;

FIG. 11 is a schematic cross-sectional view showing a fifth step of the manufacturing method of the magnetic memory device according to the first embodiment of the invention;

FIG. 12 shows the comparison between an asteroid curve 35 available in the first embodiment and an asteroid curve 36 when a recording layer 3 having an elliptical shape is employed;

FIG. 13 shows a recording layer for describing an asymmetric shape with respect to a hard axis of magnetization;

FIG. 14A shows magnetization distribution when a combination magnetic field of a magnetic field Hy in the direction of an easy axis of magnetization and a magnetic field Hx in the direction of a hard axis of magnetization is smaller than a magnetic switching field, while FIG. 14B shows magnetization distribution when the combination magnetic field of a magnetic field Hy in the direction of an easy axis of magnetization and a magnetic field Hx in the direction of a hard axis of magnetization is greater than a magnetic switching field;

FIG. 15A is a conceptual diagram of an S type magnetization distribution state, while FIG. 15B is a conceptual diagram of a C type magnetization distribution state;

FIG. 16 is a graph showing the heat treatment temperature dependence of the coercivity of a cobalt iron boron film having a boron content of 10, 20, or 30 (at %) (atomic percent);

FIG. 17 is a graph showing the heat treatment temperature dependence of the magnetic switching field of the recording layer 3 made of a cobalt iron boron film having a boron content of 20 or 30 (at %);

FIG. 18 is a graph showing the heat treatment temperature dependence of the distribution in magnetic switching field of the recording layer 3 having a boron content of 20 or 30 (at %);

FIG. 19 is a graph showing the anneal temperature dependence of an increase rate in coercivity of a cobalt iron boron film before or after heat treatment at 300° C.;

FIG. 20 is a graph showing the boron content dependence of a magnetoresistance ratio in the magnetic memory element MM;

FIG. 21 is a schematic view showing the cross-sectional structure of a magnetic memory element according to a second embodiment of the invention;

FIG. 22 is a schematic view showing the cross-sectional structure of a magnetic memory element according to a third embodiment of the invention;

FIG. 23 is a cross-sectional view of a recording layer 3 of a magnetic memory device according to a fourth embodiment;

FIG. 24 is a plan view showing a modification example of the shape of a recording layer;

FIG. 26 is a plan view showing another modification example of the shape of a recording layer; and

### DETAILED DESCRIPTION

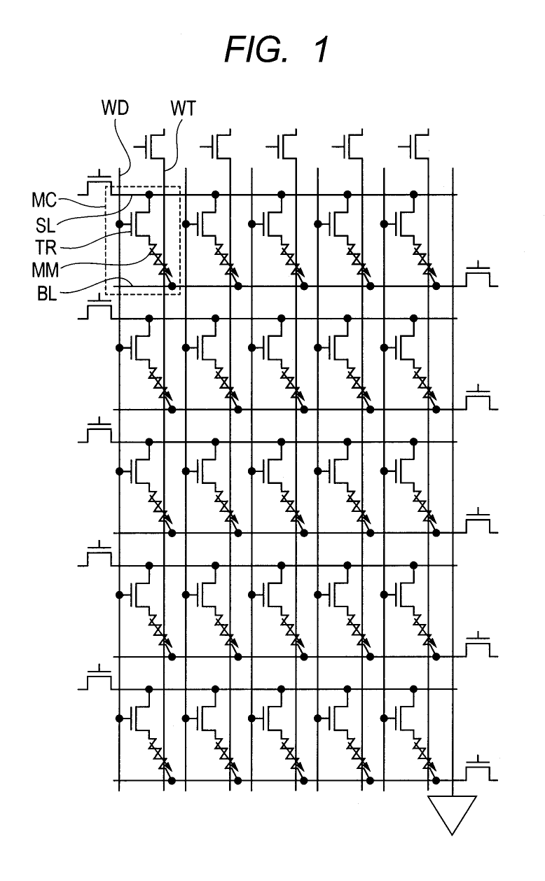

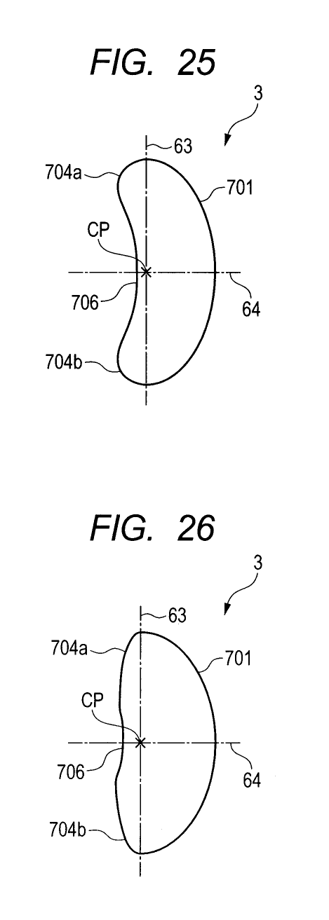

Referring to FIGS. 1 to 26, the magnetic memory device according to embodiments of the invention will be described.

### First Embodiment

### (Circuit and Structure of Memory Cell)

First, with regards to the magnetic memory device according to the present embodiment of the invention, a description will be made on the circuit of a memory cell of the magnetic memory device.

FIG. 1 is a circuit diagram of a memory cell of the magnetic memory device according to the first embodiment of the invention. Referring to FIG. 1, in the magnetic memory device, a memory cell MC (within a dotted line) is comprised of an element selection transistor TR and a magnetic memory element (ferromagnetic tunnel junction element) MM. A plurality of the memory cells MC are arranged in a matrix form.

For the magnetic memory elements MM, a write line WT and a bit line BL for rewriting and reading information intersect with each other. A plurality of the bit lines BL are arranged in one direction (for example, row).

A plurality of the write lines WT are each electrically coupled to the other end side of each of the magnetic memory elements MM arranged in the other direction (for example, column). The magnetic memory element MM is, on the other end of the magnetic memory element MM, electrically coupled to an element selection transistor TR on the drain side thereof. The respective source sides of a plurality of the element selection transistors TR arranged in one direction are electrically coupled together through a source line SL. The respective gates of the element selection transistors TR arranged in the other direction are electrically coupled through a word line WD.

The structure of the magnetic memory device according to the present embodiment will next be described.

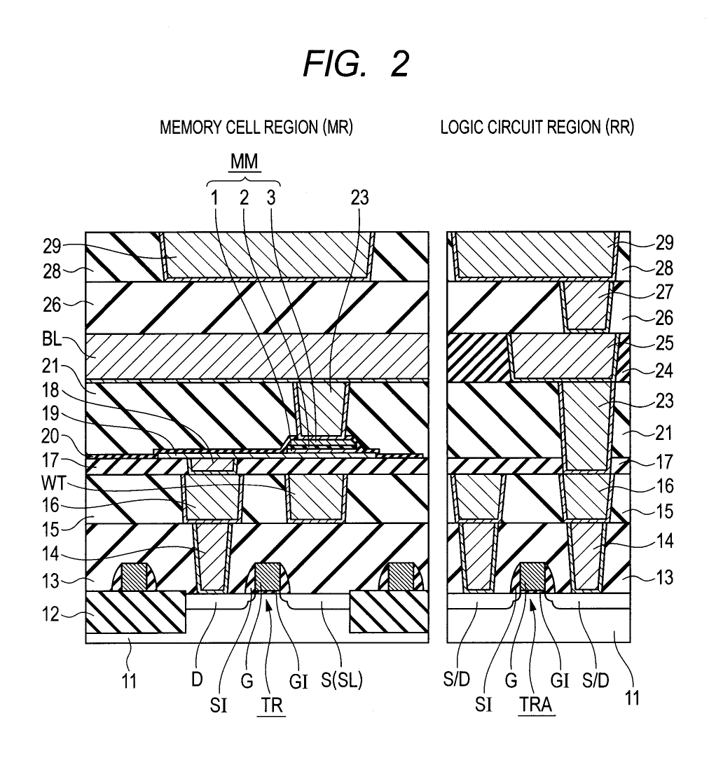

FIG. 2 is a schematic cross-sectional view showing the configuration of the magnetic memory device according to the first embodiment of the invention. Referring to FIG. 2, in a memory cell region MR of a semiconductor substrate 11, an element selection transistor TR is formed on the surface (the surface of the semiconductor substrate 11) of an element formation region partitioned with an element isolation insulating film 12. The element selection transistor TR has mainly a drain region D, a source region S, and a gate electrode G. The drain region D and the source region S are formed in the surface of the semiconductor substrate 11 with a predetermined distance therebetween. The drain region D and the source region S are each formed of an impurity region of a predetermined conductivity type. The gate electrode G is formed over a region sandwiched between the drain region D and the source region S with a gate insulating film GI therebetween. The side wall of the gate electrode G is covered with a sidewall insulating film SI in the form of sidewall.

An interlayer insulating film 13 covers the element selection transistor TR therewith. The interlayer insulating film 13 has therein a hole starting from the top surface of the interlayer insulating film and reaching the drain region D. This hole has a coupling member 14 therein. The interlayer insulating film 13 has thereon an interlayer insulating film 15. This interlayer insulating film 15 has therein a hole starting from the top surface of the interlayer insulating film and reaching the coupling member 14 and another hole reaching the interlayer insulating film 13. These holes have therein the write line WT and a wiring layer 16. The wiring layer 16 is electrically coupled to the drain region D via the coupling member 14.

An interlayer insulating film 17 is formed on the interlayer insulating film 15 so as to cover therewith the write line WT and the wiring layer 16. The interlayer insulating film 17 has therein a hole extending from the top surface of the interlayer insulating film to the wiring layer 16. The hole has a coupling member 18 therein. The interlayer insulating film 17 has thereon a conductive layer 19 and a magnetic memory element MM. The conductive layer 19 is electrically coupled to the drain region D via the coupling members 18, 16, and 14.

The magnetic memory element MM is a magnetoresistive effect element and it has a pinned layer 1, a tunnel insulating layer 2 which is a non-magnetic layer, and a recording layer 3 which have been stacked one after another in order of mention. The pinned layer 1 is brought into contact with the conductive layer 19.

A protective film 20 is formed to cover therewith the magnetic memory element MM and the protective film 20 has thereon an interlayer insulating film 21. This protective film 20 and the interlayer insulating film 21 have therein a hole penetrating through the protective film 20 and the interlayer insulating film 21 and reaching the recording layer 3. This hole has therein a coupling member 23. The interlayer insulating film 21 has thereon a bit line BL. This bit line BL is electrically coupled to the magnetic memory element MM via the coupling member 23.

An interlayer insulating film 26 is formed to cover therewith the bit line BL. The interlayer insulating film 26 has thereon a predetermined wiring layer 29 and an interlayer insulating film 28. The write line WT and the bit line BL are placed with a space in a thickness direction of the semiconductor substrate 11 and the bit line BL is placed above the write line WT.

In a peripheral (logic) circuit region RR of the semiconductor substrate 11, a transistor TRA forming a logic circuit is formed. This transistor TRA has a pair of source/drain regions S/D formed in the surface of the semiconductor substrate 11 with a predetermined distance therebetween and a gate electrode G formed on a region sandwiched between these source/drain regions S/D via a gate insulating film GI. The gate electrode G has sidewalls covered with a sidewall insulating film SI in the form of sidewalls.

This transistor TRA has thereon predetermined wiring layers 16, 25, and 29, coupling members 14, 23, and 27 for electrically coupling the wiring layers 16, 25, and 29, and interlayer insulating films 13, 15, 17, 21, 24, 26, and 28.

The structure of the memory cell will next be described more specifically.

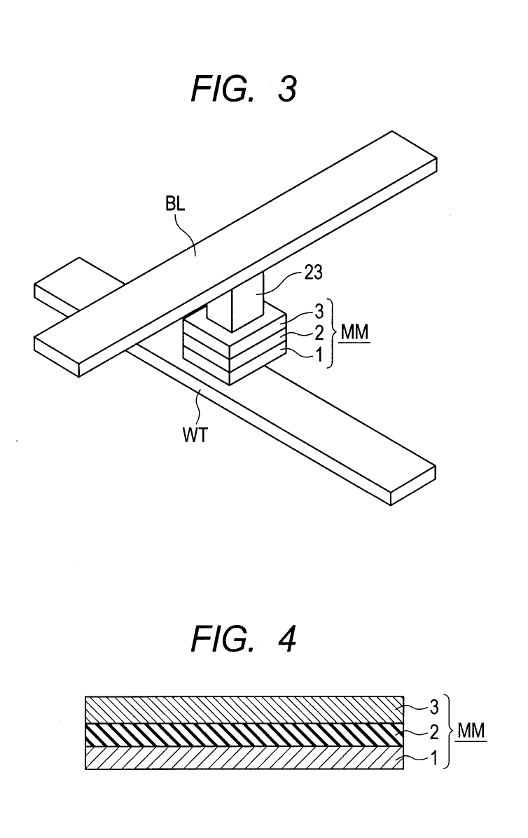

FIG. 3 is a perspective view schematically illustrating the configuration of the vicinity of the magnetic memory element MM. FIG. 4 is a cross-sectional view schematically showing the configuration of the magnetic memory element. Referring to FIG. 3, when the write line WT and the bit line BL are viewed planarly from the thickness direction of the semiconductor substrate 11, the magnetic memory element MM to be magnetized for information is placed so as to be sandwiched vertically between the write line WT and the bit line BL in a region where the write line WT and the bit line BL intersect each other. The magnetic memory element MM has, for example, a stack structure of the pinned layer 1, the tunnel insulating layer 2, and the recording layer 3. In the pinned layer 1, a magnetization direction is fixed, while in the recording layer 3, the magnetization direction changes with a magnetic field that occurs due to an electric current passing through a predetermined wiring (for example, the bit line BL) or injection of spin-polarized electrons.

The pinned layer 1 of the magnetic memory element MM is electrically coupled to the drain region D of the element selection transistor TR via the conductive layer 19 and the coupling members 18, 16, and 14 as illustrated in FIG. 2. On the other hand, the magnetic memory element MM on the side of the recording layer 3 is electrically coupled to the bit line BL via the coupling member 23.

The recording layer 3 whose magnetization direction changes with a magnetic field applied from the outside has usually a direction (easy magnetization direction) in which magnetization is likely to occur, depending on the crystal structure or shape. Energy is low in this direction. A virtual axis line extending in a direction in which magnetization is likely to occur is designated as an easy axis of magnetization (Ea: Easy-axis), while a virtual axis line extending in a direction (hard magnetization direction) in which magnetization is less likely to occur is designated as a hard axis of magnetization (Ha: Hard-axis).

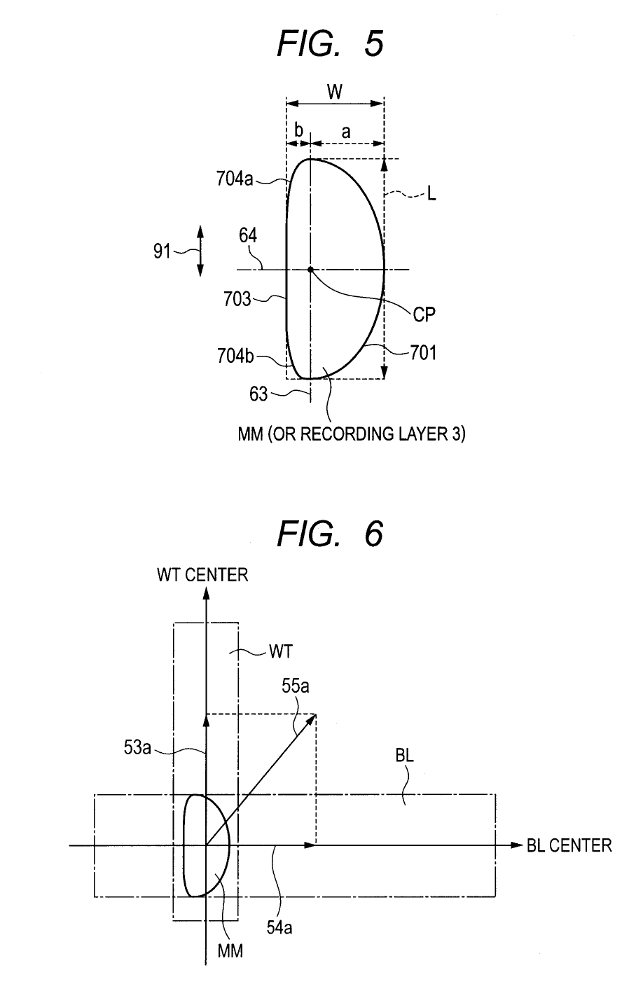

One mode of the shape, in the planar view, of the magnetic memory element MM according to the present embodiment is as illustrated in FIG. 5. Referring to FIG. 5, a direction parallel to the direction (easy magnetization direction) indicated with an arrow 91 is a direction of the easy axis of magnetization 63. A direction perpendicular to this easy axis of magnetization 63 is a direction of the hard axis of magnetization 64. The easy axis of magnetization 63 lies at a position at which the recording layer 3 in this direction has the maximum length.

The hard axis of magnetization 64 extends so that it equally divides the easy axis of magnetization 63 where the recording layer 3 is located. Unavoidably, an intersection CP is a point where the hard axis of magnetization 64 and the easy axis of magnetization 63 intersect with each other.

In the recording layer 3 illustrated in FIG. 5, an outer edge portion located on the right side of the easy axis of magnetization 63 is formed of an elliptical arc 701 and an outer edge portion located on the left side of the easy axis of magnetization 63 is formed of a straight line portion 703. One of the end portions of the arc 701 is coupled to one of the end portions of the straight line portion 703 via a curved portion 704a, while the other end portion of the arc 701 is coupled to the other end portion of the straight line portion 703 via a curved portion 704b. It is preferred that these curved portions 704a and 704b have an equal curvature and the recording layer 3 is symmetrical with respect to the hard axis of magnetization 64. The recording layer 3 symmetric with respect to the hard axis of magnetization 64 and asymmetric with respect to the easy axis of magnetization 63 is preferred.

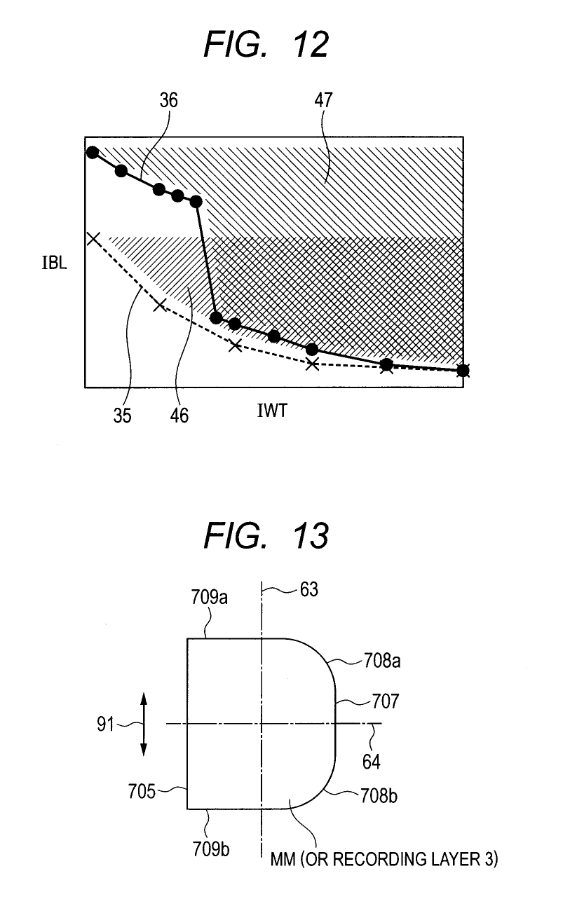

According to the magnetic memory element equipped with the recording layer 3 having such a planar shape, the magnetic switching field can be made greater in a magnetic memory element not selected and can be made smaller in a magnetic memory element selected compared with that of the conventional magnetic memory element. This enables the selection of a magnetic memory element with improved reliability. The reason for it will be described later referring to FIGS. 12 and 13.

With respect to the planar shape, the recording layer 3 has a maximum length L in the direction of the easy axis of magnetization 63 on a straight line along the easy axis of magnetization. In addition, the recording layer 3 is situated over a length W smaller than half of the length L in the extending direction of the hard axis of magnetization 64. A portion of the recording layer 3 on the right side (one side) of the easy axis of magnetization 63 has a length a in the extending direction of the hard axis of magnetization 64. A portion of the recording layer 3 on the left side (the other side) of the easy axis of magnetization 63 has a length b in the extending direction of the hard axis of magnetization 64. The length b is shorter than the length a. The outer edge on the right side (one side) of the easy axis of magnetization 63 is composed only of the arc 701 with a smooth convex shape outward of the outer edge.

When the MRAMs are highly integrated, it becomes difficult to control the shape having a small curvature in consideration of using photolithography or etching for the formation of the recording layer 3. The arc 701 shown in FIG. 5, however, has a length equal to the maximum length L of the recording layer along the direction of the easy axis of magnetization 63, which facilitates this control and makes it possible to suppress the influence of the variation.

In the present embodiment, the pinned layer 1 and the tunnel insulating layer 2 also have the same planar shape as illustrated in FIG. 5. The shapes of them are not limited to the above-described one and, for example, only the recording layer 3 may have a curved portion and the pinned layer 1 and the tunnel insulating layer 2 may have a rectangular planar shape or these two layers may be larger than the recording layer 3 in a planar view. This means that the tunnel insulating layer 2 and the pinned layer 1 may have a similar planar shape to that of the recording layer 3 or they may have a desired planar shape including the planar shape of the recording layer 3 and having a greater area than that of the recording layer 3.

FIG. 6 is an explanatory view of the position of the magnetic memory element MM according to the first embodiment of the invention and it is a see-through plan view of the magnetic memory element. Referring to FIG. 6, the magnetic memory element MM is placed so that the direction of the easy axis of magnetization 63 is almost parallel to the extending direction of the write line WT. This means that the magnetic memory element MM is placed so that the longitudinal direction thereof is almost parallel to the extending direction of the write line WT. In addition, it is placed so that the hard axis of magnetization 64 of the magnetic memory element MM is parallel to the extending direction of the bit line BL. In the present embodiment, the write line WT and the bit line BL are formed so that their respective extending directions are almost perpendicular to each other.

### (Operation of Memory Cell)

The operation of the memory cell will next be described. Referring to FIG. 2, a read operation is performed by supplying a predetermined current to the magnetic memory element MM of a specific memory cell and detecting a difference in resistance due to the direction of magnetization. First, the element selection transistor TR of a specific memory cell is turned ON and a predetermined sense signal passes from the bit line BL and the specific magnetic memory element MM and is transmitted to the source line SL via coupling members 18, 16, and 14, and the element selection transistor TR.

When the recording layer 3 and the pinned layer 1 in the magnetic memory element MM have the same magnetization direction (parallel), the resistance is relatively low. When the recording layer 3 and the pinned layer 1 have opposite magnetization directions (anti-parallel) to each other, the resistance becomes relatively high. The tunnel magnetoresistive effect element has the following characteristic: when the recording layer 3 and the pinned layer 1 have the same magnetization direction (parallel), the resistance decreases and when the recording layer 3 and the pinned layer 1 have magnetization directions anti-parallel to each other, the resistance becomes large.

When magnetization directions of the magnetic memory element MM are parallel, the intensity of the sense signal supplied to the source line SL becomes greater than the intensity of a signal of a predetermined reference memory cell. When magnetization directions of the magnetic memory element MM are anti-parallel, on the other hand, the intensity of the sense signal becomes smaller than the intensity of the signal of the predetermined reference memory cell. Thus, whether the information written in the specific memory cell is 0 or 1 is judged by based on whether the intensity of the sense signal is greater than the intensity of the signal of the predetermined reference memory cell.

The write (rewrite) operation is carried out by supplying a predetermined current through a bit line BL and a write line WT and magnetizing (reversely magnetizing) the magnetic memory element MM. First, a predetermined current is supplied to both the selected bit line BL and write line WT to form magnetic fields (arrows 53a and 54a in FIG. 6) corresponding to the directions of current passage around the bit line BL and the write line WT, respectively. A combination magnetic field (arrow 55a in FIG. 6) of the magnetic field produced by the current passing through the bit line BL and the magnetic field produced by the current passing through the write line acts on the magnetic memory element MM positioned in the area where the selected bit line BL and write line WT intersect each other.

There are two modes, depending on the combination magnetic field: one is a mode in which the recording layer 3 of the magnetic memory element MM is magnetized in the same direction as the magnetization direction of the pinned layer 1 and the other mode in which the recording layer 3 is magnetized in the direction opposite to the magnetization direction of the pinned layer 1. Thus, both the case where the magnetization directions of the recording layer 3 and the pinned layer 1 are identical (parallel) and the case where they are opposite (anti-parallel) are implemented and these magnetization directions are recorded as information corresponding to “0” or “1.”

### (Manufacturing Method for Magnetic Memory Device)

An example of manufacturing methods of the above-described magnetic memory element and magnetic memory device will next be described.

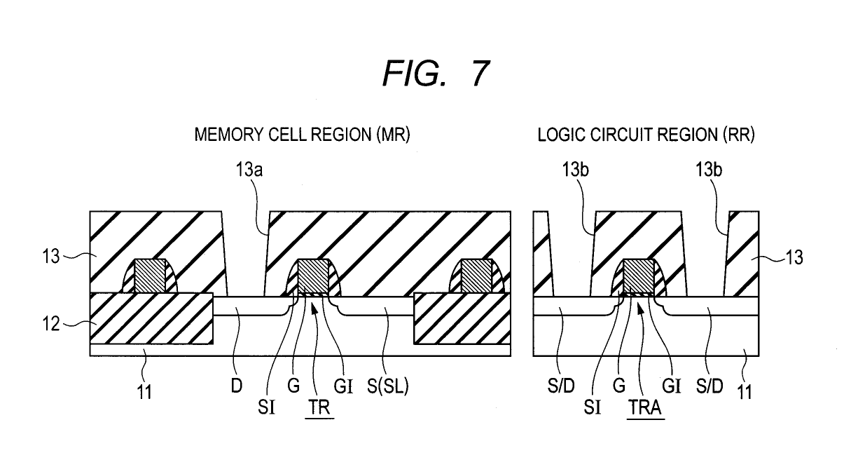

FIGS. 7 to 11 are schematic cross-sectional views showing the manufacturing method of the magnetic memory device according to the first embodiment of the present invention in the order of steps. First, referring to FIG. 7, a memory cell region MR and a peripheral circuit region RR are formed by forming element isolation insulating films 12 in predetermined regions in the main surface of a semiconductor substrate 11, respectively. Gate electrodes G are formed via gate insulating films GI on the surfaces of the semiconductor substrate 11 in the memory cell region MR and the peripheral circuit region RR, respectively. With the gate electrodes G and the like as a mask, an impurity of a predetermined conductivity type is implanted into the surface of the semiconductor substrate 11 to form a drain region D, a source region S, and a pair of source/drain regions S/D, each formed of an impurity region. Thus, an element selection transistor TR including the gate electrode G, the drain region D, and the source region S is formed in the memory cell region MR, while a transistor TRA forming a logic circuit is formed in the peripheral circuit region RR.

An interlayer insulating film 13 is formed to cover therewith the element selection transistor TR and the transistor IRA, for example, by chemical vapor deposition (CVD). With predetermined photolithography and etching of the interlayer insulating film 13, contact holes 13a and 13b exposing therefrom the surface of the semiconductor substrate 11 are formed. A barrier metal is formed on the inner circumferential surfaces of the contact holes 13a and 13b and the interlayer insulating film 13. A tungsten layer (not illustrated) is formed on the interlayer insulating film 13 to fill it in the contact holes 13a and 13b having therein the barrier metal. The barrier metal and the tungsten layer are subjected to chemical mechanical polishing (CMP) to remove a portion of the tungsten layer and the barrier metal located on the top surface of the interlayer insulating film 13.

Referring to FIG. 8, by the removal of the tungsten layer, the tungsten layer and the barrier metal have been left in each of the contact holes 13a and 13b to form a coupling member 14.

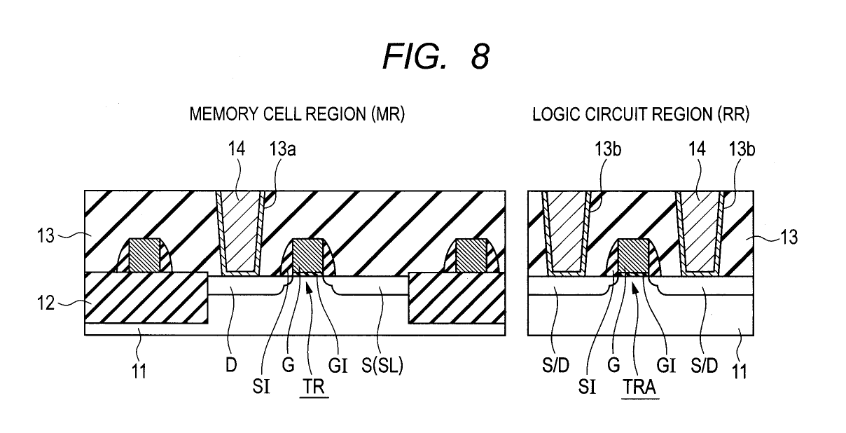

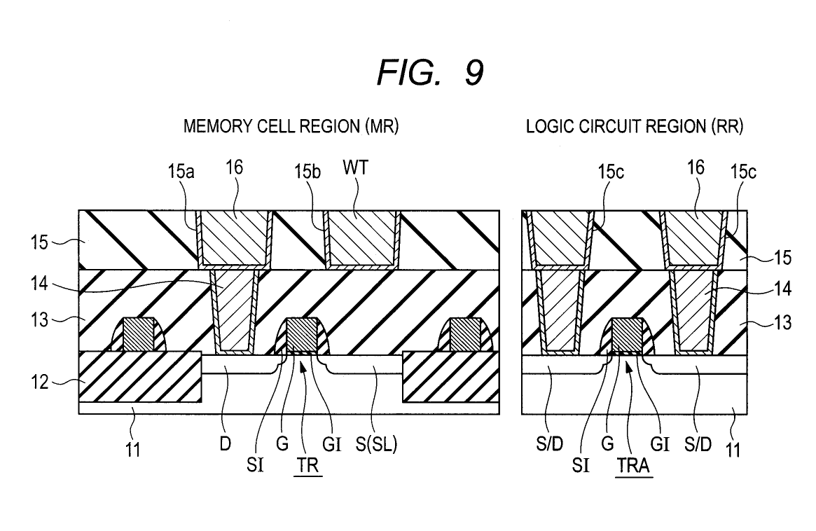

Referring to FIG. 9, another interlayer insulating film 15 is formed on the interlayer insulating film 13, for example, by CVD. The interlayer insulating film 15 is subjected to predetermined photolithography and etching to form, in the memory cell region MR, opening portions 15a and 15b for forming a write line and a predetermined wiring layer and, in the peripheral circuit region RR, an opening portion 15c for forming a predetermined wiring layer RR. A barrier metal is formed so as to cover therewith the inner circumferential surfaces of the opening portions 15a, 15b, and 15c and the top surface of the interlayer insulating film 15. For example, a copper layer (not illustrated) is formed on the interlayer insulating film 15 so as to fill it in the opening portions 15a, 15b, and 15c formed in this barrier metal. The copper layer and the barrier metal are subjected to CMP to remove the copper layer and the barrier metal on the top surface of the interlayer insulating film 15, while leaving the copper layer and the barrier metal in the opening portions 15a, 15b, and 15c. As a result, the write line WT and the wiring layer 16 are formed in the opening portion 15a and the opening portion 15b in the memory cell region MR, respectively, while the wiring layer 16 is formed in the opening portion 15c in the peripheral circuit region RR.

The barrier metals formed in the opening portions 15a, 15b, and 15c are reaction preventive films for preventing a reaction between the copper layer and the interlayer insulating film. Upon formation of the write line WT, in order to concentrate the current magnetic field of a wiring to a predetermined magnetic memory element, the copper layer may be formed as a film stack with a high magnetic permeability film. In this case, the high magnetic permeability film is opened upward.

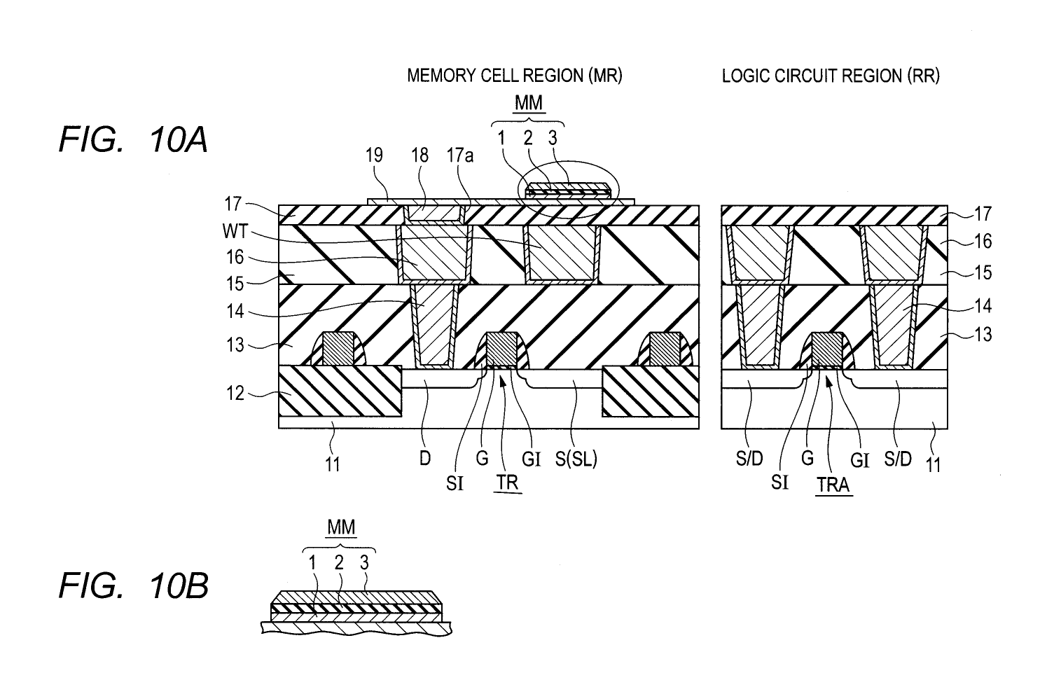

Referring to FIG. 10A, an interlayer insulating film 17 is formed on the interlayer insulating film 15, for example, by CVD. The interlayer insulating film 17 is then subjected to predetermined photolithography and etching to form a contact hole 17a exposing therefrom the surface of the wiring layer 16. A barrier metal film is formed so as to cover therewith the inner circumferential surface of the contact hole 17a, the top surface of the wiring layer 16 exposed from the contact hole 17a, and the top surface of the interlayer insulating film 17. For example, a copper layer (not illustrated) is formed on the interlayer insulating film 17 to fill the contact hole 17a having the barrier metal therein. The copper layer and the barrier metal are subjected to, for example, CMP to remove the copper layer and the barrier metal on the top surface of the interlayer insulating film 17, while leaving the copper layer and the barrier metal in the contact hole 17a, whereby a coupling member 18 is formed.

Then, a conductive layer 19 and a magnetic memory element MM are formed on the interlayer insulating film 17 in the memory cell region MR. The magnetic memory element MM is comprised of a pinned layer 1, a tunnel insulating film 2, and a recording layer 3. First a thin film which will be the conductive layer 19 is formed using a metal material. Then, as a film to be the pinned layer 1, for example, a platinum manganese film (anti-ferromagnetic layer) having a thickness of about 20 nm and a cobalt iron alloy film (ferromagnetic layer) having a thickness of about 3 nm are formed successively. Then, for example, an aluminum oxide film having a thickness of about 1 nm is formed as a film to be the tunnel insulating film 2.

Then, a cobalt iron boron alloy film having a thickness of about 3 nm is formed as a film to be the recoding layer 3. This cobalt iron boron alloy film has cobalt (Co), iron (Fe), and boron (B) as main components and inevitable impurities as the remainder. This cobalt iron boron alloy film has a boron content greater than 21 (at %), more preferably greater than 22 (at %) (atomic percent). Then, as a film to be an electrode, a tantalum film having a thickness of about 200 nm is formed, though not illustrated.

The platinum manganese film, cobalt iron alloy film, aluminum oxide film, cobalt iron boron alloy film, and tantalum film described above are formed using sputtering. The composition ratio of the cobalt iron alloy or cobalt iron boron alloy can be adjusted by using sputtering targets different in composition and controlling the respective powers, while discharging at the same time.

Then, the thin metal film which will be the conductive layer 19, the platinum manganese film, the cobalt iron alloy film, the aluminum oxide film, the cobalt iron boron alloy film, and the tantalum film are subjected to predetermined photolithography and etching to form the magnetic memory element MM of a predetermined shape including the conductive layer 19, the pined layer 1, the tunnel insulating layer 2, and the recording layer 3. It is the common practice to use a gas composed mainly of oxygen when the dry process (ashing) is employed for the removal of the resist pattern after etching. The gas is preferably not oxidative with respect to the constituent material of the pinned layer 1 or the recording layer 3. For example, hydrogen, nitrogen, or ammonia, or a mixture thereof is used so that oxidation of the pinned layer 1 or the recording layer 3 can be inhibited.

Incidentally, the pinned layer 1 may have a stack structure of an anti-ferromagnetic layer, a ferromagnetic layer, a non-magnetic layer, and a ferromagnetic layer. As the recording layer 3, a stack structure of ferromagnetic films different in magnetic property or a stack structure of a ferromagnetic layer, a non-magnetic layer, and a ferromagnetic layer may be employed without a problem.

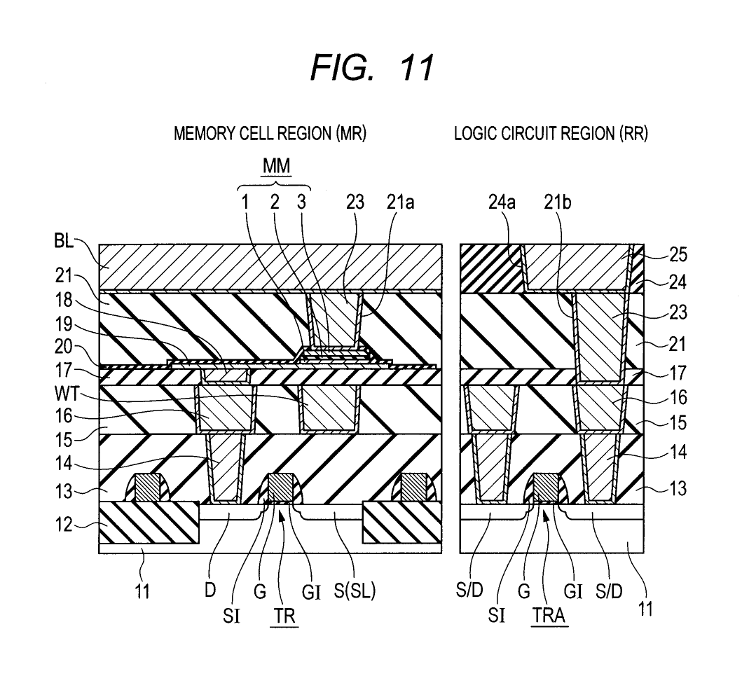

Referring to FIG. 11, in order to prevent the magnetic memory element MM from being damaged in a process performed later, a protective film 20 is formed so as to cover the magnetic memory element MM. A further interlayer insulating film 21 is formed on the interlayer insulating film 17, for example, by CVD to cover the protective film 20. In the memory cell region MR, the interlayer insulating film 21 and the protective film 20 are subjected to predetermined photolithography and etching to form a contact hole 21a exposing therefrom the surface of the recording layer 3. In the peripheral circuit region RR, the interlayer insulating film 21 and the interlayer insulating film 17 are subjected to predetermined photolithography and etching to form a contact hole 21b reaching the surface of the wiring layer 16.

A barrier metal is then formed to cover the inner circumferential surface of these contact holes 21a and 21b, the top surface of the tantalum film for electrode which is exposed from the contact hole 21a, the top surface of the wiring layer 16 exposed from the contact hole 21b, and the top surface of the interlayer insulating film 21.

For example, a copper layer (not illustrated) is formed on the interlayer insulating film 21 to fill it in the contact holes 21a and 21b having the barrier metal therein. The copper layer and the barrier metal are subjected to, for example, CMP to remove the copper layer and the barrier metal on the top surface of the interlayer insulating film 21, while leaving the copper layer and the barrier metal in each of the contact holes 21a and 21b, whereby a coupling member 23 is formed.

An interlayer insulating film 24 is formed on the interlayer insulating film 21, for example, by CVD to cover therewith the interlayer insulating film 21. The interlayer insulating film 24 is subjected to predetermined photolithography and etching to form an opening portion for forming a bit line in the interlayer insulating film 24 in the memory cell region MR and to form an opening portion 24a in the interlayer insulating film 24 in the peripheral circuit region RR. A barrier metal is formed on the inner circumferential surface of this opening portion 24a, the top surface of the coupling member 23 exposed from the opening portion 23a, and the top surface of the interlayer insulating film 24. For example, a copper layer (not illustrated) is formed on the interlayer insulating film 24 so as to fill it in the opening portion 24a having the barrier metal therein. The copper layer and the barrier metal are subjected to, for example, CMP to remove the copper layer and the barrier metal on the top surface of the interlayer insulating film 24. As a result, the copper layer remains in the opening portion for the bit line and thus, a bit line BL is formed and a wiring layer 25 is formed from the copper layer which has remained in the opening portion 24a.

The single damascene process has so far been described, but after successive formation of the interlayer insulating film 21 and the interlayer insulating film 24, a predetermined coupling member and a wiring layer may be formed in these interlayer insulating films 21 and 24 by the dual damascene process. In this case, first, the interlayer insulating film 24 is subjected to predetermined photolithography and etching to form an opening portion (not illustrated) for forming a bit line in the memory cell region MR and an opening portion 24a for forming a wiring layer in the peripheral circuit region RR. The interlayer insulating film 21 is then subjected to predetermined photolithography and etching, by which a contact hole 21a reaching the surface of the recording layer 3 of the magnetic memory element MM is formed in the memory cell region MR and a contact hole 21b reaching the surface of the wiring layer 16 is formed in the peripheral circuit region RR. An opening portion 24a may be formed in the interlayer insulating film 24 after formation of a contact hole in the interlayer insulating films 21 and 24.

For example, a copper layer (not illustrated) is formed on the interlayer insulating film 24 so as to fill it in the contact holes 21a and 21b and the opening portion 24a. The copper layer is subjected to, for example, CMP to remove a portion of the copper layer located on the top surface of the interlayer insulating film 24. As a result, a coupling member 23 buried in the contact hole 21a and electrically coupled to the recording layer 3 is formed in the memory cell region MR and at the same time, a bit line BL to be electrically coupled to the coupling member 23 is formed in the opening portion. The coupling member 23 is not essential insofar as the bit line BL and the recording layer 3 can be electrically coupled to each other. On the other hand, in the peripheral circuit region RR, a coupling member 23 to be electrically coupled to the wiring layer 16 is formed in the contact hole 21b and at the same time, a wiring layer 25 to be electrically coupled to the coupling member 23 is formed in the opening portion 24a.

Referring FIG. 2, an interlayer insulating film 26 is formed on the interlayer insulating film 24 so as to cover the bit line BL and the wiring layer 25 thus formed. In the peripheral circuit region RR, a hole is formed in the interlayer insulating film 26 and a coupling member 27 is formed in the hole. An interlayer insulating film 28 is formed on the interlayer insulating film 26. An opening portion is formed in this interlayer insulating film 28 and a wiring layer 29 formed in the opening portion.

A description was given by taking the single damascene process as an example of the above formation method, but after successive formation of the interlayer insulating film 26 and the interlayer insulating film 28, the coupling member 27 and the wiring layer 29 may be formed in these interlayer insulating films 26 and 28 by using the dual damascene process similar to the above case. In such a manner, the magnetic memory device of the present embodiment is manufactured.

In the above manufacturing method of the magnetic memory device, a description was given by taking the tungsten layer as an example of the coupling member 14. Instead, silicon may be used. A metal such as copper, titanium, or tantalum may also be used. Further, an alloy of such a metal or a nitride of such a metal may be used. A description was made by taking CMP or RIE as an example of the formation method of the coupling member 14, but, for example, plating, sputtering, or CVD may be employed instead. When copper is used as the metal, a so-called damascene process can be used and the coupling member 14 can be formed in parallel with the wiring layer.

A description was given by taking the single damascene process as the formation process of the write line WT. When the write line WT and the coupling member 14 are formed simultaneously, the dual damascene process may be employed. Further, when a metal such as silicon, tungsten, aluminum, or titanium, an alloy of such a metal, or a compound of such a metal is used as the wiring material, a wiring may be formed by dry etching.

Thickness of the interlayer insulating film present between two wiring layer varies, depending on an application device, but in the present magnetic memory device, its film thickness is, for example, about 40 nm.

A description was given by taking an aluminum oxide as an example of the tunnel insulating film 2 of the magnetic memory element MM. As the tunnel insulating layer 2, a non-magnetic material is preferred. Preferred examples of the tunnel insulating layer 2 include oxides of a metal such as aluminum, silicon, tantalum, or magnesium, nitrides of the metal, alloy oxides of the metal typified by silicate, and nitrides of the alloy. The tunnel insulating layer 2 is formed preferably as a relatively thin film having a thickness of approximately from about 0.3 to 5 nm. Incidentally, when a non-magnetic metal material is used instead of the tunnel insulating layer 2, the so-called giant magnetoresistive effect in a perpendicular direction relative to the film surface can be utilized.

As the pinned layer 1 of the magnetic memory element MM, a stack structure of a platinum manganese alloy film and a cobalt iron alloy film was given as an example. The pinned layer 1 is comprised of preferably a ferromagnetic material having, for example, nickel, iron and/or cobalt as main components. For the improvement of the magnetic property and thermal stability, an additive such as boron, nitrogen, silicon or molybdenum may be incorporated in the ferromagnetic material.

The magnetization direction can be fixed further when the pinned layer 1 has a stack structure of an anti-ferromagnetic layer and a ferromagnetic layer. This means that since the anti-ferromagnetic layer fixes the direction of the spin of the ferromagnetic layer, the magnetization direction of the ferromagnetic layer can be kept constant. As the anti-ferromagnetic layer, a compound of manganese with at least one ferromagnetic material such as iron or noble metal is preferred. The magnetization can be stabilized by employing such a film stack structure.

In the above manufacturing method, sputtering is employed as an example of a method for forming each of the pinned layer 1, the tunnel insulating layer 2, and the recording layer 3 configuring the magnetic memory element. It is also possible to form each of the pinned layer 1, the tunnel insulating layer 2, and the recording layer 3 by using, as well as sputtering, molecular beam epitaxy (MBE), chemical vapor deposition, or vacuum deposition.

In the above manufacturing method of the magnetic memory device, described was the case where the conductive layer 19 is placed between the pinned layer 1 of the magnetic memory element MM and the coupling member 18. The pinned layer 1 may be directly coupled to the coupling member 18. Alternatively, the wiring layer 16 and the conductive layer 19 may be directly coupled to each other without the coupling member 18 therebetween. In this case, in a planar view of the pinned layer 1 and the conductive layer 19, the conductive layer 19 may have a similar shape to the planar shape of the pinned layer 1 so that the conductive layer 19 overlaps with the pinned layer 1. As the material of the conductive layer 19, using a low resistance metal such as platinum, ruthenium, copper, aluminum, or tantalum is preferred. The thickness of the conductive layer 19 is, for example, preferably 300 nm or less so as not to impair the evenness of the pinned layer 1, the tunneling insulating layer 2, and the recording layer 3 formed over the conductive layer.

When the pinned layer 1 and the recording layer 3 are formed with the same size in planar view, the conductive layer 19 should be larger than the pinned layer 1 in a planar view in order to couple the conductive layer 19 to the coupling member 14. No problem occurs in the magnetic memory element even if the conductive layer 19 is thus greater than the pinned layer 1 in a planar view.

When the predetermined conductive layer 19 is placed between the interlayer insulating film 15 and the magnetic memory element MM and the coupling member 18 is formed of, for example, copper, it is possible to prevent the coupling member 18 comprised of copper from corrosion upon pattering of the magnetic memory element MM by etching. In addition, it is possible to reduce the resistance of a current pathway upon reading and improve the read speed by using, for the conductive layer 19, a material having lower resistance than that of the pinned layer 1 of the magnetic memory element MM.

Furthermore, in the above magnetic memory device of the present embodiment, the case where the protective film 20 covers the magnetic memory element MM to prevent the magnetic memory element MM from being damaged in a step subsequent to the formation of the magnetic memory element MM was taken as an example. The treatment in the manufacturing step during which the magnetic memory element MM may be damaged is, for example, heat treatment upon formation of an interlayer insulating film. When a silicon oxide film is formed as the interlayer insulating film, the silicon oxide film is formed under an oxidizing atmosphere as high as approximately 300° C.

At this time, there is a possibility of the magnetic film being oxidized under the oxidizing atmosphere. This sometimes deteriorates the magnetic property of the magnetic memory element MM. When the magnetic memory element MM is covered with a protective film 20 such as silicon nitride film or aluminum oxide film, the protective film 20 serves as a barrier of this oxidation and can protect the magnetic memory element MM.

The interlayer insulating film may have a two-layer structure comprised of a thin film, such as silicon nitride film, that can be formed under a non-oxidizing atmosphere and an oxidizing insulating film. In this case, the silicon nitride film, among the two films forming the interlayer insulating film, serves as a protective film of the magnetic memory element MM.

Furthermore, as the protective film 20, a film containing at least one material selected from insulating metal nitrides, insulating metal carbides, and metal oxides formed by oxidation treatment of a metal having a lower oxide formation free energy than Fe is preferred. Using such a material can at least prevent the magnetic memory element MM from being oxidized in an oxidation step among manufacturing steps of the magnetic memory device using an Fe-containing magnetic material thin film. As a result, a magnetic memory device easy to manufacture and stable in operation characteristics can be obtained. In the present embodiment, all of the above manufacturing steps are performed at 300° C. as the maximum temperature.

### (Action and Effect)

The action and effect of the magnetic memory device according to the present embodiment will next be described.

FIG. 12 shows an example of a magnetization switching current when the recording layer 3 has a shape as illustrated in FIG. 5. In FIG. 12, a write line current IWT to be supplied to the write line WT for causing a magnetic field Hx in the direction of a hard-axis of magnetization is plotted along the abscissa, while a bit line current IBL to be supplied to a bit line BL for causing a magnetic filed Hy in the direction of an easy-axis of magnetization. This graph also includes a magnetization switching current when the recording layer 3 has an elliptical shape. The measurement points plotted in the graph are measurement results of a bit line current IBL necessary for switching the magnetization direction when a predetermined write line current is applied while the magnetization direction of the recording layer 3 is in a negative direction of the magnetic field Hy. This means that lines coupling respective plots to each other are asteroid lines 35 and 36 of the recording layer 3 in the shape illustrated in FIG. 5 and in elliptical shape.

Thus, a region 46 permitting magnetization switching (hatched region in this diagram) of the recording layer increases due to asymmetry of the shape with respect to the hard-axis of magnetization. This makes it possible to increase the region 46 permitting magnetization switching of the recording layer over a region 47 of an elliptical shape which is symmetric with respect to the hard-axis of magnetization.

Here, FIG. 13 is used for describing the reason why such an effect can be produced. In FIG. 13, the recording layer 3 has, in a planar shape thereof, linear straight line portions 707 and 705 in the direction of the easy-axis of magnetization 63 and linear straight line portions 709a and 709b in the direction of the hard-axis of magnetization 64 (an axial direction perpendicular to the easy-axis of magnetization 63). The straight line portion 705 and the straight line portion 709b are perpendicular at the intersection. The straight line portion 705 and the straight line portion 709a are perpendicular at the intersection. On the other hand, the straight line portion 709a and the straight line portion 707 are coupled to each other via a curved portion 708a, while the straight line portion 709b and the straight line portion 707 are coupled to each other via a curved portion 708b. The straight line portion 707 and the straight line portion 705 are parallel to each other. The straight line portion 709a and the straight line portion 709b are parallel to each other. In the present embodiment, the curved portion 708a and the curved portion 708b each forms an arc. In other words, the planar shape of the recording layer 3 is asymmetry with respect to the easy-axis of magnetization 63 and line-symmetry with respect to the hard-axis of magnetization 64 (axis perpendicular to the easy-axis of magnetization 63).

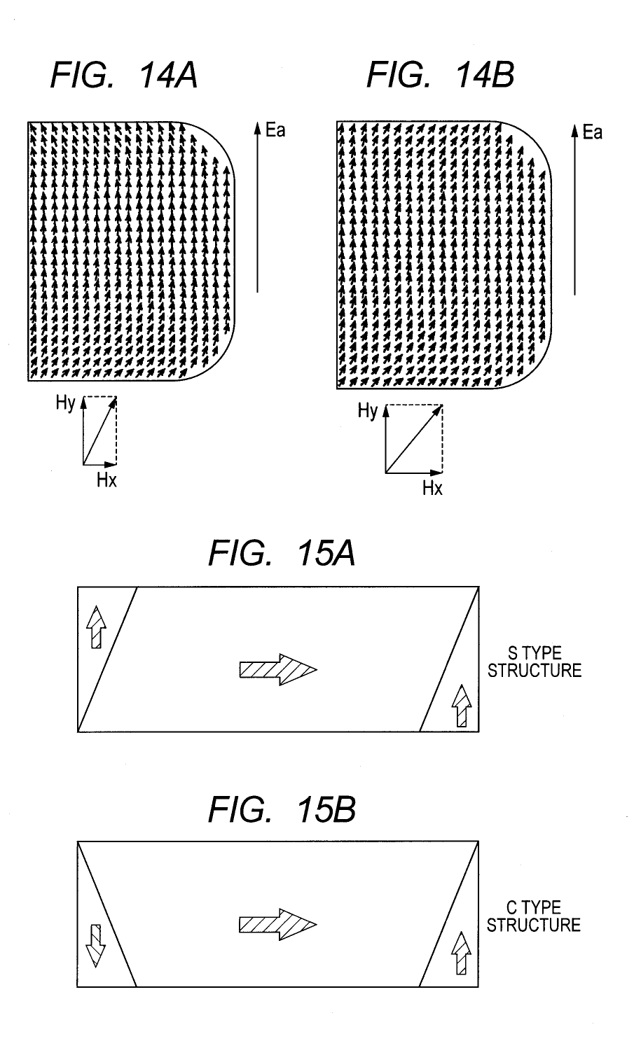

As the plot 35 of FIG. 12 shows, the intensity of the bit line current IBL necessary for magnetization switching varies greatly, depending on the intensity of the write line current IWT. This phenomenon originates from a difference in the magnetization state. FIGS. 14A and 14B show magnetization distributions in respective cases where a combination magnetic field of a magnetic field Hy in an easy axis of magnetization and a magnetic field Hx in a hard axis of magnetization is smaller and where it is laeger than a magnetic switching field. They are plan view of the recording layer 3 of the magnetic memory element MM illustrated in FIG. 13. The arrows in the recording layer illustrated in FIGS. 14A and 14B show magnetization directions at respective positions. In these two diagrams of FIGS. 14A and 14B, a magnetic field is applied so that the intensity of the magnetic field Hy is the same but the intensity of the magnetic field Hx is different. The magnetic field Hx applied in FIG. 14A is smaller than the threshold value in the direction of the hard axis of magnetization and the magnetic field Hx applied in FIG. 14B is greater than the threshold value in the direction of the hard axis of magnetization.

The pattern of the magnetization distribution as illustrated in FIG. 14A is designated as C type (first magnetization distribution). In the C type magnetization distribution, the magnetization state is stable and the magnetic switching field in the direction of easy axis of magnetization becomes greater. On the other hand, the pattern of the magnetization distribution as illustrated in FIG. 14B is designated as S type (second magnetization distribution). The S type magnetization distribution is susceptible to torque arising from an external magnetic field and the magnetic switching field becomes drastically smaller. FIGS. 15A and 15A are conceptual diagrams illustrating the states of S type and C type magnetization distributions. The recording layer 3 in the present embodiment has a planar shape permitting control of the states of S type and C type magnetization distributions by an external magnetic field. The recording layer 3 illustrated in FIG. 5 also assumes the same magnetization distribution states.

Returning, as described above, the recording layer 3 illustrated in FIG. 5 has, as a portion thereof on the right side of the easy axis of magnetization 63, an arc 701. When MRAMs are loaded with high integration, a shape with a small curvature cannot be formed with good control due to photolithography or etching step for the formation of the recording layer 3. The arc 701 in FIG. 5 is an arc having a length equal to the maximum length of the recording layer so that it can be controlled easily and is not influenced by the variation. Instead of the arc, another curved line may be employed.

The above recording layer 3 makes use of magnetic distribution derived from its shape. Generally, the magnetic switching field of a recording layer is described with both anisotropy which the film itself has and anisotropy which the shape produces. In order to produce the above effect in the recording layer 3 of the present embodiment, contribution of magnetic anisotropy derived from the shape should be made greater relatively. The anisotropy of the film itself should be reduced and at the same time, the recording layer should have a uniform property therein. To satisfy these conditions, the recording layer is preferably amorphous.

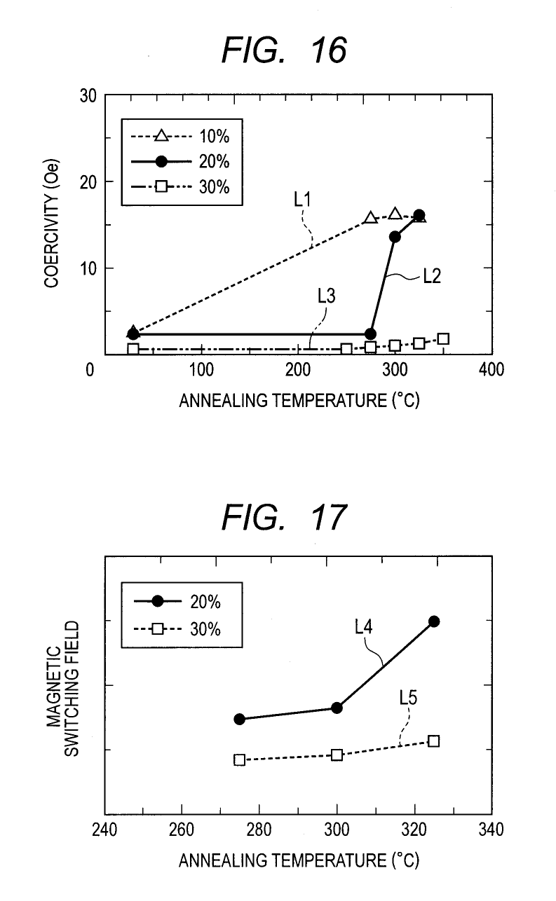

FIG. 16 is a graph showing the annealing temperature dependence of the coercivity of three cobalt iron boron alloys having a boron content of 10, 20, and 30 (at %), respectively. The annealing temperature (° C.) is plotted along the abscissa, while the coercivity (Oe (ersted)) is plotted along the ordinate. The broken line L1 in the graph shows the property of the cobalt iron boron alloy having a boron content of 10 (at %). The solid line L2 shows the property of the cobalt iron boron alloy having a boron content of 20 (at %). A two-dot chain line L3 shows the property of the cobalt iron boron alloy having a boron content of 30 (at %). An increase in coercivity due to an increase in annealing temperature is observed in any case. The graph shows the results of crystallization of an amorphous alloy caused by heat. When the content is 10%, an increase is observed at 275° C. and when the content is 20%, an increase is observed at 300° C. This means that crystallization proceeds at a lower temperature when a boron content is small.

FIG. 17 is a graph showing the annealing temperature dependence of the magnetic switching field of two cobalt iron boron alloys having a boron content of 20 (at %) and 30 (at %), respectively. The annealing temperature (° C.) is plotted along the abscissa and the magnetic switching field (Oe) is plotted along the ordinate. A solid line L4 shows the property of a cobalt iron boron alloy having a boron content of 20 (at %) and a broken line L5 shows the property of a cobalt iron boron alloy having a boron content of 30 (at %). A great increase in magnetic switching field between 300° C. to 325° C. is observed in the cobalt iron boron alloy having a boron content of 20 (at %). At this time, a distribution in magnetic switching field illustrated in FIG. 18 also shows a great increase, which results from an increase in the crystal magnetic anisotropy energy due to crystallization and an increase in local dispersion thereof.

In the graph of FIG. 18, the annealing temperature (° C.) is plotted along the abscissa and the distribution in magnetic switching field is plotted along the ordinate. The solid line L6 in the graph shows a distribution in magnetic switching field of a plurality of cobalt iron boron alloy films having a boron content of 20 (at %). The broken line L7 shows a distribution in magnetic switching field of a plurality of cobalt iron boron alloy films having a boron content of 30 (at %).

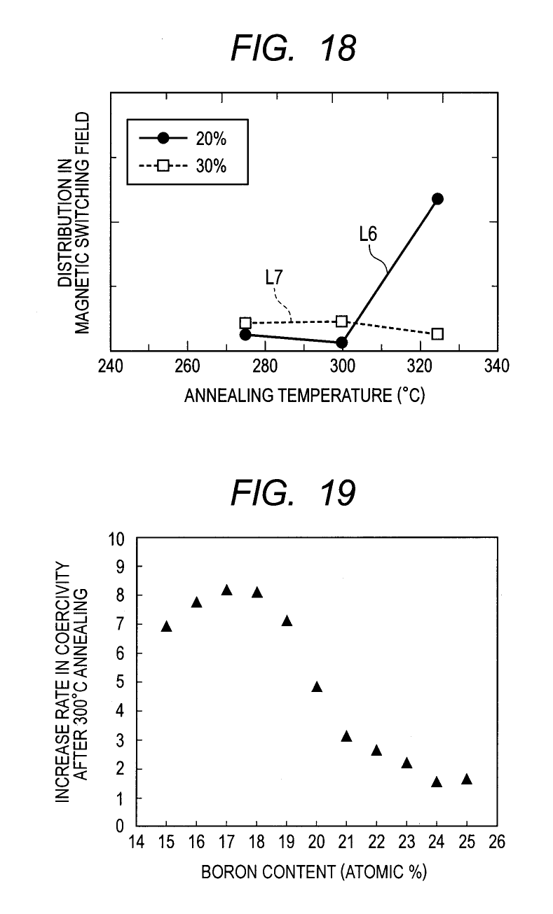

A wiring step is usually performed at approximately 300° C. so that evaluation results of the boron content dependence of an increase rate of coercivity after heat treatment at 300° C. are shown in FIG. 19. In the graph of FIG. 19, a boron content in the cobalt iron alloy film is plotted along the abscissa and an increase rate in coercivity of a cobalt iron alloy film after annealing at 300° C. is plotted along the ordinate. The graph of FIG. 19 shows, as can be seen from the plot in the graph, an increase rate of coercivity of a plurality of cobalt iron boron alloys different in boron content.

As illustrated in FIG. 19, an increase rate in coercivity after heat treatment is marked when the boron content is 21 (at %) or less. This means that when heat treatment at 300° C. is taken into consideration, an increase in magnetic switching field or an increase in distribution in magnetic switching field occurs as shown in FIGS. 17 and 19 when the boron content is 21 (at %) or less. An increase in the magnetic switching field of the recording layer 3 leads to an increase in a write current. When there appears a distribution in magnetic switching field in a plurality of the recording layers 3, reliability in writing decreases.

When a cobalt iron boron alloy film having a boron content exceeding 21 (at %) is used as the recording layer 3, on the other hand, changes before and after heat treatment are small so that the film has a stable property throughout manufacturing steps. Using, as the recording layer 3, a cobalt iron boron alloy film having a boron content exceeding 21 (at %), more preferably a cobalt iron boron alloy film having a boron content of 22 (at %) or greater can therefore suppress an increase in magnetic switching field before and after heat treatment and at the same time, can suppress a distribution in magnetic switching field among the recording layers 3. As a result, it is possible to reduce a write current and enhance the reliability in writing.

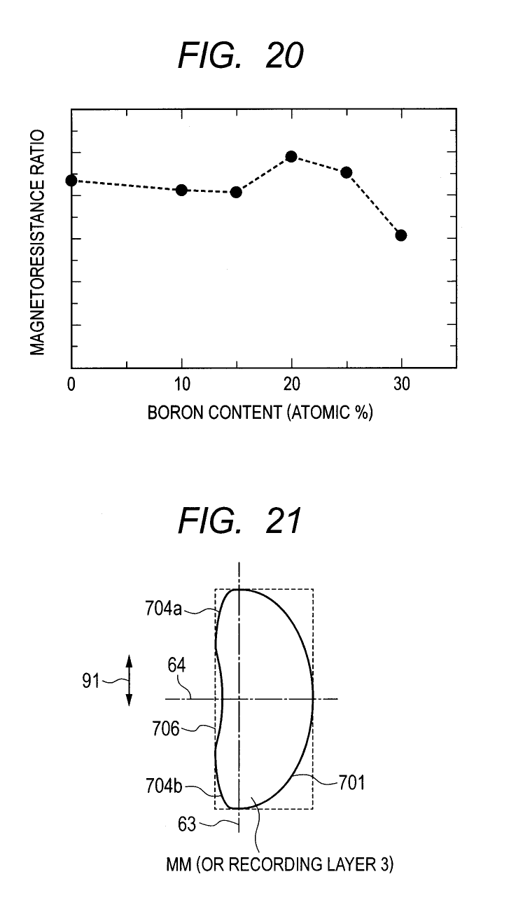

The influence on the write characteristic has so far been described. The boron content in a cobalt iron boron alloy has an influence on the read characteristic of the recording layer 3. FIG. 20 is a graph showing the boron content dependence of a magnetoresistance ratio in the magnetic memory element MM. The boron content (at %) is plotted along the abscissa, while the magnetoresistance ratio is plotted along the ordinate. As shown in this graph, the magnetoresistance ratio reaches its peak at a boron content around 20 (at %) and shows a drastic decrease at 25 (at %) or greater. From the standpoint of the reading operation, the boron content is preferably 25 (at %) or less.

Thus, the recording layer 3 is formed of preferably a cobalt iron boron alloy film having cobalt, iron, and boron as main components, having inevitable impurities as the remainder, and having a boron content exceeding 21 (at %) but not greater than 25 (at %).

The magnetic memory device having the recording layer 3 comprised of such an alloy film can be operated at high speed because a write current and its variation are suppressed and at the same time, a large signal can be obtained in a reading operation. In a high-integrated device such as MRAM, a great variation in magnetic property among a plurality of recording layers makes it difficult to control its write characteristic.

### Second Embodiment

Referring to FIG. 21, a magnetic memory device according to a second embodiment will next be described. FIG. 21 is a plan view of a recording layer of the magnetic memory device according to the second embodiment. The recording layer 3 is comprised of a material similar to that used in the first embodiment, that is, cobalt iron boron. The boron content is 22 (at %) which is greater than 21 (at %). With regards to the planar shape of the recording layer 3 in this embodiment, it has, on the right side of the easy axis of magnetization 63, an elliptical arc 701 and, on the left side of the easy axis of magnetization 63, a curved portion 706. The curved portion 706 is coupled to, at the upper portion and the lower portion thereof, a curved portion 704a and 704b having the same curvature, respectively and the curved portions 704a and 704b are coupled to the elliptical arc 701. The shape of the present embodiment in which the curved portions 704a and 704b have an equal curvature produces a similar effect to the shape illustrated in FIG. 5. Since it has a convex portion as shown by the curved portion 706, an asymmetric shape with respect to the easy axis of magnetization produces a greater effect. The other operation and effect are similar to those of the first embodiment so that the description on them is omitted.

### Third Embodiment

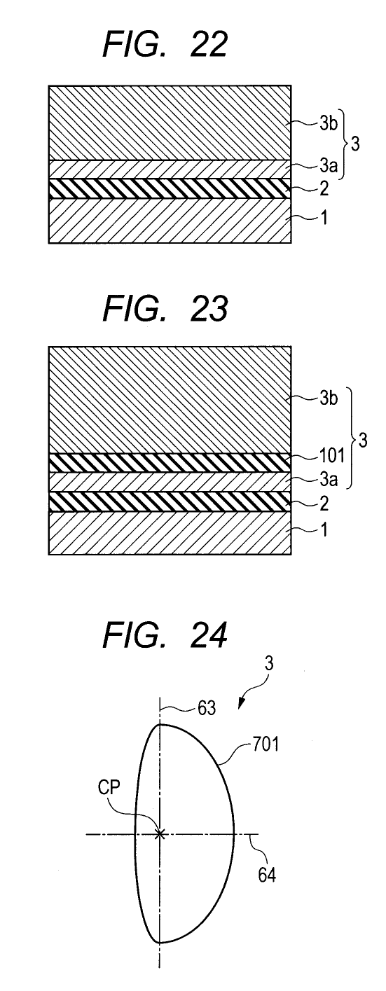

Referring to FIG. 22, a magnetic memory device according to a third embodiment will next be described. FIG. 22 is a cross-sectional view of a recording layer 3 of the magnetic memory device according to the third embodiment. The recording layer 3 shown in FIG. 22 is similar in planar shape or the other configuration to that of the first embodiment. It has a stack structure of a cobalt iron boron alloy film 3b having a thickness of 4 nm and a boron content of 22 (at %) and a ferromagnetic film 3a having a thickness of 1 nm. The ferromagnetic film 3a is brought into contact with the top surface of the tunnel insulating layer 2 and the cobalt iron boron alloy film 3b is brought into contact with the top surface of the ferromagnetic film 3a.

A tunnel insulating layer 2 is made of, for example, an Al₂O₃ film. As the ferromagnetic film 3a, a cobalt iron alloy or a cobalt iron boron alloy having a boron content less than 22 (at %) is employed. More specifically, as the ferromagnetic film 3a, a cobalt iron boron alloy film containing cobalt, iron, and boron and having a boron content less than 22 at % or a cobalt iron alloy film having cobalt and iron as main components and having inevitable impurities as the remainder is used. The cobalt iron boron alloy film 3b is preferably a cobalt iron boron alloy film having cobalt, iron, and boron as main components and inevitable impurities as the remainder and having a boron content of 22 (at %) or greater but not greater than 25 (at %).

Since the cobalt iron boron alloy film 3b is thicker than the ferromagnetic film 3a, the property of the cobalt iron boron alloy film 3b becomes dominant in magnetization switching. With regards to the read characteristic, the property of the ferromagnetic film 3a is dominant. The ferromagnetic film 3a has a high magnetoresistance ratio as its property as shown in FIG. 20. Using two ferromagnetic films in combination enables independent control of write characteristic and read characteristic.

### Fourth Embodiment

Referring to FIG. 23, a magnetic memory device according to a fourth embodiment will next be described. FIG. 23 is a cross-sectional view showing a recording layer 3 of the magnetic memory device according to the fourth embodiment. As illustrated in FIG. 23, the recording layer 3 is comprised of a stack structure of a cobalt iron boron alloy film 3b having a thickness of 5 nm and a boron content of 22 (at %), a ruthenium film 101 having a thickness of 1 nm, and a ferromagnetic film 3a having a thickness of 1 nm. The ferromagnetic film 3a is formed on the top surface of an Al₂O₃ film which is the tunnel insulating film 2, and the ruthenium film 101 is formed on the top surface of the cobalt iron boron alloy film 3b. The ruthenium film 101 has, on the top surface thereof, the cobalt iron boron alloy film 3b. In this case, the magnetizations of the cobalt iron boron alloy film 3b and the ferromagnetic film 3a are coupled with each other in the anti-ferromagnetic manner via the ruthenium film 101. Apparent magnetization of the recording layer 3 can therefore be indicated as a difference in magnetization between two ferromagnetic films.

Using the above configuration enables an increase in the volume of the recording layer 3 without increasing a write current. This makes it possible to suppress fluctuations in magnetization which will otherwise be caused by the heat due to size reduction, leading to improvement in reliability in data retention.

The recording layer 3 of the fourth embodiment also contains a cobalt iron alloy film so that similar to the recording layer 3 of the third embodiment, it can have the read characteristic of the ferromagnetic film 3a. The other operation is similar to that of the first embodiment so that a description on it is omitted. Also in the fourth embodiment, the cobalt iron boron alloy film 3b preferably has cobalt, iron, and boron as main components, has inevitable impurities as the remainder, and has a boron content of 22 (at %) or greater but not greater than 25 (at %). The ferromagnetic film 3a is either a cobalt iron boron alloy film having cobalt, iron, and boron and having a boron content less than 22 (at %) or a cobalt iron alloy film having cobalt and iron as main components and having inevitable impurities as the remainder.

In a high integrated device such as MRAM, it is virtually difficult to manufacture the magnetic memory elements MM while keeping the shape of the recording layer 3 constant. So, from the practical standpoint, the shapes shown in FIGS. 5, 13, and 21 were introduced as the shape of the recording layer. When any of these shapes is employed, it is possible to suppress fluctuations in wiring current upon magnetization switching due to the asymmetry of the shape in the surface direction of the recording layers 3 of the magnetic memory elements arranged in a matrix form. Modification examples of the shape of the recording layer 3 other than those are shown in FIGS. 24 to 26.

Also in examples shown in FIGS. 24 to 26, the planar shape of the recording layer 3 is asymmetry with respect to the easy axis of magnetization 63 and line-symmetry with respect to the hard axis of magnetization 64. Also in examples shown in FIGS. 24 to 26, the recording layer 3 has the maximum length in the extending direction of the easy axis of magnetization 63 and the length of it in the extending direction of the hard axis of magnetization 64 is shorter than half of the maximum length. A portion of the recording layer 3 on the right side (on one side) of the easy axis of magnetization 63 is longer than a portion of it on the left side (on the other side), each from the easy axis of magnetization 63. An outer edge of the portion of the recording layer 3 on the right side of the easy axis of magnetization 63 is an arc 701. Therefore, similar effects to those shown in FIG. 5 can be obtained also in the examples shown in FIGS. 24 to 26.

The above-described characteristics are useful in a memory device itself but are more useful in a device having the memory cell and a logic circuit in combination. In the latter device, network environments and interactive environments for handling information in mobile communication are improved based on high-speed operation. Further, power consumption can be reduced and operating environments can be significantly improved by applying these magnetic memory devices to computers, portable terminals, and the like.

In the above-described magnetic memory elements and magnetic memory devices, magnetic memory devices making use of a semiconductor substrate was taken as an example. However, the relationship between magnetoresistance effect elements and wiring layers related to write lines and bit lines is not limited to memory of information. This relationship can be applied widely to patterned magnetic elements, for example, magnetic sensors, magnetic record heads, and magnetic recording media.

Furthermore, in the above-described magnetic memory elements and magnetic memory devices, every memory cell has a magnetic memory element, but a memory cell may be equipped with two or more magnetic memory elements. Further, these memory cells may be stacked one after another.

The embodiments disclosed herein are merely examples in every respect and the invention is not limited to these embodiments. The invention is not shown by the scope of the description described above but by the scope of claims. It is intended that the invention embraces the equivalent meaning as the scope of the claims, and all the changes within the scope.

The invention can be advantageously applied to magnetic memory devices equipped with a magnetoresistive effect element having a tunnel magnetoresistive effect.

What is claimed is:

1. A magnetic memory device, comprising:
a substrate;
a first wiring provided over the substrate;
a second wiring placed with a space from the first wiring in a thickness direction of the substrate and extending in a direction intersecting with an extending direction of the first wiring; and
a magnetic memory element positioned between the first wiring and the second wiring,
wherein the magnetic memory element includes a pinned layer whose magnetization direction has been fixed and a recording layer whose magnetization direction changes depending on an external magnetic field,
wherein the recording layer contains an alloy film, and
wherein the alloy film contains cobalt, iron, and boron and has a boron content exceeding 21 at %.

2. The magnetic memory device according to claim 1, wherein the boron content is 25 at % or less.

3. The magnetic memory device according to claim 1, wherein the recording layer is a stack of the alloy film and a first ferromagnetic film thinner than the alloy film.

4. The magnetic memory device according to claim 3,
wherein the magnetic memory element contains a tunnel insulating film between the recording layer and the pinned layer,
wherein the first ferromagnetic film is formed over the tunnel insulating film, and
wherein the alloy film is formed over the first ferromagnetic film.

5. The magnetic memory device according to claim 3,
wherein the first ferromagnetic film is either a cobalt iron boron alloy film containing cobalt, iron, and less than 22 at % of boron or a cobalt iron alloy film having cobalt and iron as main components and having inevitable impurities as the remainder.

6. The magnetic memory device according to claim 1,
wherein the recording layer contains a second ferromagnetic film thinner than the alloy film and a nonmagnetic film placed between the second ferromagnetic film and the alloy film.

7. The magnetic memory device according to claim 6,
wherein the magnetic memory element contains a tunnel insulating film between the recording layer and the pinned layer,
wherein the second ferromagnetic film is provided over the tunnel insulating film,
wherein the non-ferromagnetic film is provided over the second ferromagnetic film, and
wherein the alloy film is provided over the non-ferromagnetic film.

8. The magnetic memory device according to claim 1,
wherein assuming that a direction along which the recording layer is easy to magnetize is designated as an easy magnetization direction and a virtual axis passing through a position at which the length of the recording layer in the easy magnetization direction becomes maximum and extending in the easy magnetization direction is designated as an easy axis of magnetization, a planar shape of the recording layer is asymmetric with respect to the easy axis of magnetization.
